(19) United States
(12) Patent Application Publication
(10) Pub. No.: US 2023/0177122 A1
(43) Pub. Date: Jun. 8, 2023

(54) SIGNAL CLASSIFICATION METHOD AND APPARATUS WITH NOISE IMMUNITY, AND UNMANNED AERIAL VEHICLE SIGNAL CLASSIFICATION SYSTEM USING SAME

(71) Applicant: PUSAN NATIONAL UNIVERSITY INDUSTRY-UNIVERSITY COOPERATION FOUNDATION, Busan (KR)

(72) Inventor: Won Joo HWANG, Busan (KR)

(73) Assignee: PUSAN NATIONAL UNIVERSITY INDUSTRY-UNIVERSITY COOPERATION FOUNDATION, Busan (KR)

(21) Appl. No.: 18/076,824

(22) Filed: Dec. 7, 2022

(30) Foreign Application Priority Data
Dec. 8, 2021 (KR) 10-2021-0175065

(51) Int. Cl. G06F 18/241; G06T 11/20; B64C 39/02; G06N 3/091

(52) U.S. Cl. CPC G06F 18/241; G06T 11/206; B64C 39/024; G06N 3/091

(57) ABSTRACT

A signal classification method with noise immunity, includes receiving a wireless training signal; combining the wireless training signal with a white Gaussian noise signal, based on a preset desired signal-to-noise ratio (SNR), to generate a modulation signal resulting from modulating an SNR of the wireless training signal to correspond to the preset desired SNR; generating, based on a signal resulting from performing short-time Fourier transform on the modulation signal, a power-based spectrogram image corresponding to the wireless training signal; inputting the power-based spectrogram image and a predetermined supervised learning value corresponding to the wireless training signal into a preset convolution neural network (CNN) model to train the preset CNN model; generating, based on a signal resulting from performing short-time Fourier transform on the wireless evaluation signal, a power-based spectrogram image corresponding to the wireless evaluation signal; and classifying the wireless evaluation signal by applying the power-based spectrogram image.

### CROSS REFERENCE TO RELATED APPLICATION

The application claims the benefit under 35 USC 119(a) of Korean Patent Application No. 10-2021-0175065, filed Dec. 8, 2021, the entire disclosure of which is incorporated herein by reference for all purposes.

### BACKGROUND

### 1. Field

The present disclosure relates to a signal classification method and apparatus with noise immunity, and an unmanned aerial vehicle signal classification system using the method and the apparatus.

### 2. Description of the Related Art

Unmanned aerial vehicles (UAVs), including drones, are used for various purposes, such as delivery, agriculture, transportation, communication, etc. The global coronavirus disease-2019 (COVID-19) pandemic has increased the need to develop contactless and remote technologies, and the demand for unmanned aerial vehicles (UAVs) has rapidly increased.

As the use and demand for unmanned aerial vehicles have increased in various fields, abuse cases of unmanned aerial vehicles, such as invasion of privacy, drug trafficking, terror using drones, etc., have also increased. Thus, drone restriction zones and drone flight regulations have been made, but a low barrier to entry to purchase drones is likely to pose many dangers due to drones.

Therefore, it may be desirable to develop an anti-UAV system to curb the malicious use of drones. The anti-UAV system protects personal property and information from unauthorized unmanned aerial vehicles, and consists of three operations: detection, identification, and determination. Herein, the detection of a drone must precede the determination operation so that the anti-UAV system can operation normally and perform successful defense.

Regarding drone detection, technologies using radar, sound, vision, and radio frequency have been introduced. Compared to the vision method, the radar-based drone detection technology is free from the effects of fine dust, fog, and weather and does not require line of sight (LOS), but is optimized for aircraft operating at high altitudes, making it difficult to detect drones flying at low altitudes.

In addition, the sound-based drone detection technology detects drones by analyzing the sound generated when a blushless motor in the drone rotates at high speed, has a very short detection distance, and is sensitive to noise. The vision-based detection method may be limited because of fog, weather, and obstacles.

The radio frequency (RF)-based drone detection technology detects drones by intercepting RF signals between the drones and controllers, and is relatively free from constraints, such as weather, noise, etc., compared to the other methods. However, classification accuracy is also reduced when the signal-to-noise ratio (SNR) is reduced. When the distance between an RF receiver and a drone increases and the SNR is reduced, drone detection accuracy decreases.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a signal classification method with noise immunity, includes receiving a wireless training signal including a plurality of voltage values corresponding to a plurality of time points based on time; combining the wireless training signal with a white Gaussian noise signal, based on a preset desired signal-to-noise ratio (SNR), to generate a modulation signal resulting from modulating an SNR of the wireless training signal to correspond to the preset desired SNR; generating, based on a signal resulting from performing short-time Fourier transform on the modulation signal, a power-based spectrogram image corresponding to the wireless training signal; inputting the power-based spectrogram image and a predetermined supervised learning value corresponding to the wireless training signal into a preset convolution neural network (CNN) model to train the preset CNN model; receiving a wireless evaluation signal; generating, based on a signal resulting from performing short-time Fourier transform on the wireless evaluation signal, a power-based spectrogram image corresponding to the wireless evaluation signal; and classifying the wireless evaluation signal by applying the power-based spectrogram image corresponding to the wireless evaluation signal to the preset CNN model.

The generating of the modulation signal may include using averages of the voltage values of a previous section and a subsequent section with any intermediate time point, among the time points of the wireless training signal, to detect any one of the time points included in the wireless training signal as a transient state start point with a maximum average change; separating, from the wireless training signal, a signal section signal excluding a noise section, and including the plurality of voltage values corresponding to the plurality of time points at and after the transient state start point; generating the white Gaussian noise signal based on a power ratio of the signal section signal with respect to the preset desired SNR; and combining the wireless training signal with the white Gaussian noise signal to generate the modulation signal resulting from the modulation of the SNR of the wireless training signal to correspond to the desired SNR.

The generating of the white Gaussian noise signal may include calculating a signal power value by squaring sizes of the voltage values of the signal section signal; dividing the signal power value by the preset desired SNR to calculate a noise power value; and generating the white Gaussian noise signal by multiplying a square root of the noise power value by a preset Gaussian distribution function.

The generating of the power-based spectrogram image corresponding to the wireless training signal may include calculating a power density signal by performing short-time Fourier transform on the modulation signal and by squaring an absolute value of a signal resulting from short-time Fourier transform; setting an average power of the modulation signal as a threshold value; and using the threshold value to perform filtering on a power value based on a value obtained by integrating the power density signal on a per preset frequency region basis at each frequency, and generating the power-based spectrogram image including a plurality of pixel values corresponding to time and frequency domains.

In another general aspect, a signal classification apparatus with noise immunity, includes a wireless training signal input part configured to receive a wireless training signal including a plurality of voltage values corresponding to a plurality of time points based on time; a modulation signal generation module configured to combine the wireless training signal with a white Gaussian noise signal, based on a preset desired signal-to-noise ratio (SNR), to generate a modulation signal resulting from modulating an SNR of the wireless training signal to correspond to the preset desired SNR; a wireless evaluation signal input part configured to receive a wireless evaluation signal; a spectrogram image generation part configured to generate a power-based spectrogram image corresponding to the wireless training signal based on a signal resulting from performing short-time Fourier transform on the modulation signal, and generate a power-based spectrogram image corresponding to the wireless evaluation signal on based on a signal obtained by performing short-time Fourier transform on the wireless evaluation signal; a training part configured to input the power-based spectrogram image corresponding to the wireless training signal and a predetermined supervised learning value corresponding to the wireless training signal into a preset convolution neural network (CNN) model to train the preset CNN model; and a signal classification part configured to apply the power-based spectrogram image corresponding to the wireless evaluation signal to the preset CNN model trained.

The modulation signal generation module may include a signal section separation part configured to use averages of the voltage values of a previous section and subsequent section with any intermediate time point, among the time points of the wireless training signal, to detect any one of the time points included in the wireless training signal as a transient state start point with a maximum average change, and separate, from the wireless training signal, a signal section signal excluding a noise section, and including the plurality of voltage values corresponding to the plurality of time points at and after the transient state start point; a noise generation part configured to generate the white Gaussian noise signal according to a power ratio of the signal section signal with respect to the preset desired SNR; and a noise combination part configured to combine the wireless training signal with the white Gaussian noise signal to generate the modulation signal resulting from modulation such that the SNR of the wireless training signal corresponds to the desired SNR.

The noise generation part may be further configured to calculate a signal power value by squaring sizes of the voltage values of the signal section signal, calculate a noise power value by dividing the signal power value by the preset desired SNR, and generate the white Gaussian noise signal by multiplying a square root of the noise power value by a preset Gaussian distribution function.

The spectrogram image generation part may be further configured to calculate a power density signal for the modulation signal or the wireless evaluation signal by squaring an absolute value of a signal obtained by performing short-time Fourier transform on the modulation signal or the wireless evaluation signal, set an average power of the modulation signal or the wireless evaluation signal as a threshold value, use the threshold value set for the modulation signal or the wireless evaluation signal to perform filtering on a power value based on a value obtained by integrating the power density signal for the modulation signal or the wireless evaluation signal on a per preset frequency region basis at each frequency, and generate the power-based spectrogram image corresponding to the wireless training signal or the wireless evaluation signal and including a plurality of pixel values corresponding to time and frequency domains.

In another general aspect, an unmanned aerial vehicle signal classification system, includes a signal database configured to store a plurality of wireless training signals respectively corresponding to a plurality of unmanned aerial vehicle controllers, and a plurality of classification values respectively corresponding to the plurality of wireless training signals; a signal measuring device configured to receive an RF signal generated from an external unmanned aerial vehicle controller and convert the RF signal into electrical energy to generate a wireless evaluation signal having a plurality of voltage values based on time; and a signal classification apparatus configured to combine the wireless training signals with white Gaussian noise signals, based on a preset desired signal-to-noise ratio (SNR), to generate modulation signals resulting from modulating SNRs of the wireless training signals to correspond to the preset desired SNR, generate power-based spectrogram images corresponding to the wireless training signals from the modulation signals, input the power-based spectrogram images corresponding to the wireless training signals and the classification values corresponding to the wireless training signals as supervised learning values into a preset convolution neural network (CNN) model to train the preset CNN model, receive the wireless evaluation signal to generate a power-based spectrogram image corresponding to the wireless evaluation signal, and apply the power-based spectrogram image corresponding to the wireless evaluation signal to the preset CNN model to classify the wireless evaluation signal.

In another general aspect, the signal classification apparatus includes a wireless training signal input part configured to receive the wireless training signals stored in the signal database; a modulation signal generation module configured to combine the wireless training signals with the white Gaussian noise signals based on the preset desired SNR to generate the modulation signals resulting from modulation such that the SNRs of the wireless training signals correspond to the desired SNR; a wireless evaluation signal input part configured to receive the wireless evaluation signal generated from the signal measuring device; a spectrogram image generation part configured to generate the power-based spectrogram images corresponding to the wireless training signals on based on signals obtained by performing short-time Fourier transform on the modulation signals, and generate the power-based spectrogram image corresponding to the wireless evaluation signal based on a signal obtained by performing short-time Fourier transform on the wireless evaluation signal; a training part configured to input the power-based spectrogram images corresponding to the wireless training signals and the supervised learning values predetermined corresponding to the wireless training signals into the preset CNN model to train the CNN model; and a signal classification part configured to apply the power-based spectrogram image corresponding to the wireless evaluation signal to the CNN model trained by the training part to classify the wireless evaluation signal.

The modulation signal generation module may include a signal section separation part configured to use averages of voltage values of a previous section and a subsequent section with any intermediate time point of each of the wireless training signals to detect any one of the time points included in each of the wireless training signals as a transient state start point with a maximum average change, and separate, from each of the wireless training signals, a signal section signal excluding a noise section, and including the plurality of voltage values corresponding to the plurality of time points at and after the transient state start point; a noise generation part configured to generate the white Gaussian noise signals based on power ratios of the signal section signals with respect to the preset desired SNR; and a noise combination part configured to combine the wireless training signals with the white Gaussian noise signals to generate the modulation signals resulting from modulation such that the SNRs of the wireless training signals correspond to the desired SNR.

The noise generation part may be further configured to calculate signal power values by squaring sizes of the voltage values of the signal section signals, calculate noise power values by dividing the signal power values by the preset desired SNR, and generate the white Gaussian noise signals by multiplying square roots of the noise power values by a preset Gaussian distribution function.

The spectrogram image generation part may be further configured to calculate a power density signal for each of the modulation signals or the wireless evaluation signal by squaring an absolute value of a signal obtained by performing short-time Fourier transform on each of the modulation signals or the wireless evaluation signal, set an average power of each of the modulation signals or the wireless evaluation signal as a threshold value, use the threshold value set for each of the modulation signals or the wireless evaluation signal to perform filtering on a power value based on a value obtained by integrating the power density signal for each of the modulation signals or the wireless evaluation signal on a per preset frequency region basis at each frequency, and generate the power-based spectrogram image corresponding to each of the wireless training signals or the wireless evaluation signal and including a plurality of pixel values corresponding to time and frequency domains.

In another general aspect, a signal classification apparatus with noise immunity, includes a wireless evaluation signal input part configured to receive a wireless evaluation signal; a spectrogram image generation part configured to generate, based on a signal obtained by performing short-time Fourier transform on the wireless evaluation signal, a power-based spectrogram image corresponding to the wireless evaluation signal; and a signal classification part configured to classify the wireless evaluation signal by applying the power-based spectrogram image corresponding to the wireless evaluation signal to a convolution neural network (CNN) model. The CNN model is previously trained to receive an external spectrogram image and output any one of a preset plurality of classification values. Wireless training signals respectively corresponding to a plurality of unmanned aerial vehicle controllers are combined with white Gaussian noise signals according to a preset desired SNR to generate modulation signals, an absolute value of a signal resulting from short-time Fourier transform of each of the modulation signals is squared to obtain a power density signal for each of the modulation signals, the power density signal is integrated on a per preset frequency region basis at each frequency to obtain a power value, the power value is filtered with an average power of each of the modulation signals, a value resulting from filtering is set as a pixel value of each pixel corresponding to time and frequency domains to generate power-based spectrogram images corresponding to the wireless training signals, and the power-based spectrogram images corresponding to the wireless training signals and predetermined supervised learning values corresponding to the wireless training signals are input to the CNN model for training.

The spectrogram image generation part may be further configured to calculate a power density signal by performing short-time Fourier transform on the wireless evaluation signal and squaring an absolute value of a signal resulting from short-time Fourier transform, set an average power of the wireless evaluation signal as a threshold value, use the threshold value to perform filtering on a power value based on a value obtained by integrating the power density signal on a per preset frequency region basis at each frequency, and generate the power-based spectrogram image corresponding to the wireless evaluation signal and including a plurality of pixel values corresponding to time and frequency domains.

Other features and aspects will be apparent from the following detailed description, the drawings, and the claims.

### BRIEF DESCRIPTION OF THE DRAWINGS

FIG. 1 is a block diagram illustrating a signal classification apparatus with noise immunity according to an embodiment of the present disclosure.

FIG. 2 is a flowchart illustrating a signal classification method with noise immunity according to another embodiment of the present disclosure.

FIG. 3 is a flowchart specifically illustrating an operation of generating a modulation signal, in the signal classification method with noise immunity according to the embodiment of the present disclosure.

FIG. 4 is a flowchart specifically illustrating an operation of generating a power-based spectrogram image corresponding to a wireless training signal, in the signal classification method with noise immunity according to the embodiment of the present disclosure.

FIG. 5 is a flowchart specifically illustrating an operation of generating a power-based spectrogram image corresponding to a wireless evaluation signal, in the signal classification method with noise immunity according to the embodiment of the present disclosure.

FIG. 6 is a block diagram illustrating an unmanned aerial vehicle signal classification system according to a still another embodiment of the present disclosure.

FIGS. 7A-7O are graphs illustrating waveforms of a wireless training signal corresponding to each of a plurality of drone controllers.

FIG. 8A is a diagram illustrating any one wireless signal therefor to describe the detection of a transient state point according to the embodiments of the present disclosure.

FIG. 8B is a J(k) waveform of FIG. 8a wireless signal therefor to describe detection of a transient state point according to the embodiments of the present disclosure.

FIG. 9A is a graph illustrating any one wireless training signal applied to the embodiments of the present disclosure.

FIG. 9B is a graph illustrating a waveform of a signal obtained by changing the SNR of the wireless training signal of FIG. 9A to 5 dB.

FIG. 9C is a graph illustrating a waveform of a signal obtained by changing the SNR of the wireless training signal of FIG. 9A to −5 dB.

FIG. 10A is a power spectral density-based spectrogram of the wireless training signal of FIG. 9A.

FIG. 10B is a power spectral density-based spectrogram of a signal obtained by changing the SNR of the wireless training signal of FIG. 9A to 5 dB.

FIG. 100 is a power spectral density-based spectrogram of a signal obtained by changing the SNR of the wireless training signal of FIG. 9A to −5 dB.

FIG. 11A is a graph illustrating a power spectrum of any one wireless training signal applied to the embodiments of the present disclosure.

FIG. 11B is a graph illustrating a power spectrum of a signal obtained by setting the SNR of the wireless training signal of FIG. 11A to −10 dB.

FIG. 12A is a diagram illustrating a power-based spectrogram image to which a threshold value according to the embodiments of the present disclosure is not applied.

FIG. 12B is a diagram illustrating a power-based spectrogram image to which a threshold value according to the embodiments of the present disclosure is applied.

FIG. 13 is a diagram illustrating a structure of a CNN model in the embodiments of the present disclosure.

FIG. 14 is a result graph illustrating classification accuracy according to SNR change when signal classification was performed using a conventional power spectral density-based spectrogram and a power-based spectrogram image with different numbers of samples per class in the embodiments of the present disclosure.

FIG. 15 is a result graph illustrating classification accuracy according to SNR change when signal classification was performed using a conventional signal classification technology and a signal classification technology according to the embodiments of the present disclosure.

Throughout the drawings and the detailed description, the same reference numerals refer to the same or like elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The present disclosure relates to a signal classification method and apparatus with noise immunity, and an unmanned aerial vehicle signal classification system using the method and the apparatus, the method, the apparatus, and the system being capable of achieving accurate signal classification even in an environment with a low SNR.

The present disclosure is directed to providing a signal classification method and apparatus with noise immunity, and an unmanned aerial vehicle signal classification system using the method and the apparatus, wherein a spectrogram image of a signal of which the SNR is modulated as a white Gaussian noise is added is applied to a CNN model, thereby achieving accurate signal classification even at a low SNR.

In addition, noise may be filtered out using an average power of the wireless signal and a power-based spectrogram image is generated, thereby maintaining signal classification accuracy stably even at a low SNR.

Developing a signal classification technology capable of detecting drones with high accuracy may be desirable even when the SNR is reduced so that the signal classification accuracy is not affected by SNR.

According to an aspect of the present disclosure, there is provided a signal classification method with noise immunity, the method including: receiving a wireless training signal including a plurality of voltage values corresponding to a plurality of time points according to time; combining the wireless training signal with a white Gaussian noise signal according to a preset desired SNR to generate a modulation signal resulting from modulation such that an SNR of the wireless training signal corresponds to the desired SNR; generating, on the basis of a signal obtained by performing short-time Fourier transform on the modulation signal, a power-based spectrogram image corresponding to the wireless training signal; inputting the power-based spectrogram image corresponding to the wireless training signal and a predetermined supervised learning value corresponding to the wireless training signal into a preset CNN model to train the CNN model; receiving a wireless evaluation signal to be subjected to signal classification; generating, on the basis of a signal obtained by performing short-time Fourier transform on the wireless evaluation signal, a power-based spectrogram image corresponding to the wireless evaluation signal; and classifying the wireless evaluation signal by applying the power-based spectrogram image corresponding to the wireless evaluation signal to the CNN model.

Herein, the generating of the modulation signal may include: using averages of the voltage values of a previous section and a subsequent section with any time point among the time points of the wireless training signal in the middle to detect any one of the time points included in the wireless training signal as a transient state start point with a maximum average change; separating, from the wireless training signal, a signal section signal excluding a noise section and including the plurality of voltage values corresponding to the plurality of time points at and after the transient state start point; generating the white Gaussian noise signal according to a power ratio of the signal section signal with respect to the preset desired SNR; and combining the wireless training signal with the white Gaussian noise signal to generate the modulation signal resulting from modulation such that the SNR of the wireless training signal corresponds to the desired SNR.

The generating of the white Gaussian noise signal may include: calculating a signal power value by squaring sizes of the voltage values of the signal section signal; dividing the signal power value by the preset desired SNR to calculate a noise power value; and generating the white Gaussian noise signal by multiplying a square root of the noise power value by a preset Gaussian distribution function.

The generating of the power-based spectrogram image corresponding to the wireless training signal may include: calculating a power density signal by performing a short-time Fourier transform on the modulation signal and by squaring an absolute value of a signal resulting from short-time Fourier transform; setting an average power of the modulation signal as a threshold value; and using the threshold value to perform filtering on a power value based on a value obtained by integrating the power density signal on a per preset frequency region basis at each frequency, and generating the power-based spectrogram image including a plurality of pixel values corresponding to time and frequency domains.

According to another aspect of the present disclosure, there is provided a signal classification apparatus with noise immunity, the apparatus including: a wireless training signal input part configured to receive a wireless training signal including a plurality of voltage values corresponding to a plurality of time points according to time; a modulation signal generation module configured to combine the wireless training signal with a white Gaussian noise signal according to a preset desired SNR to generate a modulation signal resulting from modulation such that an SNR of the wireless training signal corresponds to the desired SNR; a wireless evaluation signal input part configured to receive a wireless evaluation signal to be subjected to signal classification; a spectrogram image generation part configured to generate a power-based spectrogram image corresponding to the wireless training signal on the basis of a signal obtained by performing short-time Fourier transform on the modulation signal, and generate a power-based spectrogram image corresponding to the wireless evaluation signal on the basis of a signal obtained by performing short-time Fourier transform on the wireless evaluation signal; a training part configured to input the power-based spectrogram image corresponding to the wireless training signal and a predetermined supervised learning value corresponding to the wireless training signal into a preset CNN model to train the CNN model; and a signal classification part configured to apply the power-based spectrogram image corresponding to the wireless evaluation signal to the CNN model trained by the training part to classify the wireless evaluation signal.

Herein, the modulation signal generation module may include: a signal section separation part configured to use averages of the voltage values of a previous section and subsequent section with any time point among the time points of the wireless training signal in the middle to detect any one of the time points included in the wireless training signal as a transient state start point with a maximum average change, and separate, from the wireless training signal, a signal section signal excluding a noise section and including the plurality of voltage values corresponding to the plurality of time points at and after the transient state start point; a noise generation part configured to generate the white Gaussian noise signal according to a power ratio of the signal section signal with respect to the preset desired SNR; and a noise combination part configured to combine the wireless training signal with the white Gaussian noise signal to generate the modulation signal resulting from modulation such that the SNR of the wireless training signal corresponds to the desired SNR.

The noise generation part may be configured to calculate a signal power value by squaring sizes of the voltage values of the signal section signal, calculate a noise power value by dividing the signal power value by the preset desired SNR, and generate the white Gaussian noise signal by multiplying a square root of the noise power value by a preset Gaussian distribution function.

The spectrogram image generation part may be configured to calculate a power density signal for the modulation signal or the wireless evaluation signal by squaring an absolute value of a signal obtained by performing short-time Fourier transform on the modulation signal or the wireless evaluation signal, set an average power of the modulation signal or the wireless evaluation signal as a threshold value, use the threshold value set for the modulation signal or the wireless evaluation signal to perform filtering on a power value based on a value obtained by integrating the power density signal for the modulation signal or the wireless evaluation signal on a per preset frequency region basis at each frequency, and generate the power-based spectrogram image corresponding to the wireless training signal or the wireless evaluation signal and including a plurality of pixel values corresponding to time and frequency domains.

According to still another aspect of the present disclosure, there is provided an unmanned aerial vehicle signal classification system including: a signal database in which a plurality of wireless training signals respectively corresponding to a plurality of unmanned aerial vehicle controllers and a plurality of classification values respectively corresponding to the plurality of wireless training signals are stored; a signal measuring device configured to receive an RF signal generated from an external unmanned aerial vehicle controller and convert the RF signal into electrical energy to generate a wireless evaluation signal having a plurality of voltage values according to time; and a signal classification apparatus configured to combine the wireless training signals with white Gaussian noise signals according to a preset desired SNR to generate modulation signals resulting from modulation such that SNRs of the wireless training signals correspond to the desired SNR, generate power-based spectrogram images corresponding to the wireless training signals from the modulation signals, input the power-based spectrogram images corresponding to the wireless training signals and the classification values corresponding to the wireless training signals as supervised learning values into a preset CNN model to train the CNN model, receive the wireless evaluation signal to generate a power-based spectrogram image corresponding to the wireless evaluation signal, and apply the power-based spectrogram image corresponding to the wireless evaluation signal to the CNN model to classify the wireless evaluation signal.

Herein, the signal classification apparatus may include: a wireless training signal input part configured to receive the wireless training signals stored in the signal database; a modulation signal generation module configured to combine the wireless training signals with the white Gaussian noise signals according to the preset desired SNR to generate the modulation signals resulting from modulation such that the SNRs of the wireless training signals correspond to the desired SNR; a wireless evaluation signal input part configured to receive the wireless evaluation signal generated from the signal measuring device; a spectrogram image generation part configured to generate the power-based spectrogram images corresponding to the wireless training signals on the basis of signals obtained by performing short-time Fourier transform on the modulation signals, and generate the power-based spectrogram image corresponding to the wireless evaluation signal on the basis of a signal obtained by performing short-time Fourier transform on the wireless evaluation signal; a training part configured to input the power-based spectrogram images corresponding to the wireless training signals and the supervised learning values predetermined corresponding to the wireless training signals into the preset CNN model to train the CNN model; and a signal classification part configured to apply the power-based spectrogram image corresponding to the wireless evaluation signal to the CNN model trained by the training part to classify the wireless evaluation signal.

The modulation signal generation module may include: a signal section separation part configured to use averages of voltage values of a previous section and a subsequent section with any time point of each of the wireless training signals in the middle to detect any one of the time points included in each of the wireless training signals as a transient state start point with a maximum average change, and separate, from each of the wireless training signals, a signal section signal excluding a noise section and including the plurality of voltage values corresponding to the plurality of time points at and after the transient state start point; a noise generation part configured to generate the white Gaussian noise signals according to power ratios of the signal section signals with respect to the preset desired SNR; and a noise combination part configured to combine the wireless training signals with the white Gaussian noise signals to generate the modulation signals resulting from modulation such that the SNRs of the wireless training signals correspond to the desired SNR.

The noise generation part may be configured to calculate signal power values by squaring sizes of the voltage values of the signal section signals, calculate noise power values by dividing the signal power values by the preset desired SNR, and generate the white Gaussian noise signals by multiplying square roots of the noise power values by a preset Gaussian distribution function.

The spectrogram image generation part may be configured to calculate a power density signal for each of the modulation signals or the wireless evaluation signal by squaring an absolute value of a signal obtained by performing short-time Fourier transform on each of the modulation signals or the wireless evaluation signal, set an average power of each of the modulation signals or the wireless evaluation signal as a threshold value, use the threshold value set for each of the modulation signals or the wireless evaluation signal to perform filtering on a power value based on a value obtained by integrating the power density signal for each of the modulation signals or the wireless evaluation signal on a per preset frequency region basis at each frequency, and generate the power-based spectrogram image corresponding to each of the wireless training signals or the wireless evaluation signal and including a plurality of pixel values corresponding to time and frequency domains.

According to yet still another aspect of the present disclosure, there is provided a signal classification apparatus with noise immunity, the apparatus including: a wireless evaluation signal input part configured to receive a wireless evaluation signal to be subjected to signal classification; a spectrogram image generation part configured to generate, on the basis of a signal obtained by performing short-time Fourier transform on the wireless evaluation signal, a power-based spectrogram image corresponding to the wireless evaluation signal; and a signal classification part configured to classify the wireless evaluation signal by applying the power-based spectrogram image corresponding to the wireless evaluation signal to a CNN model, wherein the CNN model is previously trained so as to receive a spectrogram image from outside and output any one of a preset plurality of classification values, wherein wireless training signals respectively corresponding to a plurality of unmanned aerial vehicle controllers are combined with white Gaussian noise signals according to a preset desired SNR to generate modulation signals, an absolute value of a signal resulting from short-time Fourier transform of each of the modulation signals is squared to obtain a power density signal for each of the modulation signals, the power density signal is integrated on a per preset frequency region basis at each frequency to obtain a power value, the power value is filtered with an average power of each of the modulation signals, a value resulting from filtering is set as a pixel value of each pixel corresponding to time and frequency domains to generate power-based spectrogram images corresponding to the wireless training signals, and the power-based spectrogram images corresponding to the wireless training signals and predetermined supervised learning values corresponding to the wireless training signals are input to the CNN model for training.

Herein, the spectrogram image generation part may be configured to calculate a power density signal by performing short-time Fourier transform on the wireless evaluation signal and squaring an absolute value of a signal resulting from short-time Fourier transform, set an average power of the wireless evaluation signal as a threshold value, use the threshold value to perform filtering on a power value based on a value obtained by integrating the power density signal on a per preset frequency region basis at each frequency, and generate the power-based spectrogram image corresponding to the wireless evaluation signal and including a plurality of pixel values corresponding to time and frequency domains.

Advantages and features of the present disclosure, and methods to achieve them will be apparent from the following embodiments that will be described in detail with reference to the accompanying drawings. It should be understood that the present disclosure is not limited to the following embodiments and may be embodied in different ways, and that the embodiments are given to provide complete the disclosure and to provide a thorough understanding of the present disclosure to those skilled in the art. The scope of the present disclosure is defined only by the claims. The terms used herein are provided to describe the embodiments but not to limit the present disclosure. In the specification, the singular forms include plural forms unless particularly mentioned.

According to the present disclosure, a CNN model is trained using a spectrogram image of a signal obtained by intentionally reducing the SNR of a wireless training signal used for training, so that accurate classification is achieved even for a wireless signal having a low SNR.

In addition, a power-based spectrogram image is generated rather than a conventional power spectral density-based spectrogram image, and in generating the spectrogram image, filtering is performed using an average power of a signal, thereby improving signal classification accuracy.

Hereinafter, a signal classification method and apparatus with noise immunity, and an unmanned aerial vehicle signal classification system using the method and the apparatus according to embodiments of the present disclosure will be described in detail with reference to the accompanying drawings.

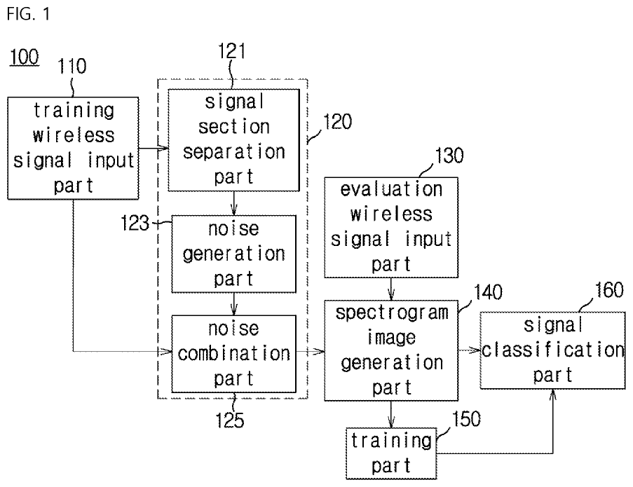

Referring to FIG. 1, a signal classification apparatus 100 with noise immunity according to an embodiment of the present disclosure may include a wireless training signal input part 110, a modulation signal generation module 120, a wireless evaluation signal input part 130, a spectrogram image generation part 140, a training part 150, and a signal classification part 160.

The signal classification apparatus with noise immunity according to the embodiment of the present disclosure may perform a signal classification method with noise immunity according to another embodiment of the present disclosure.

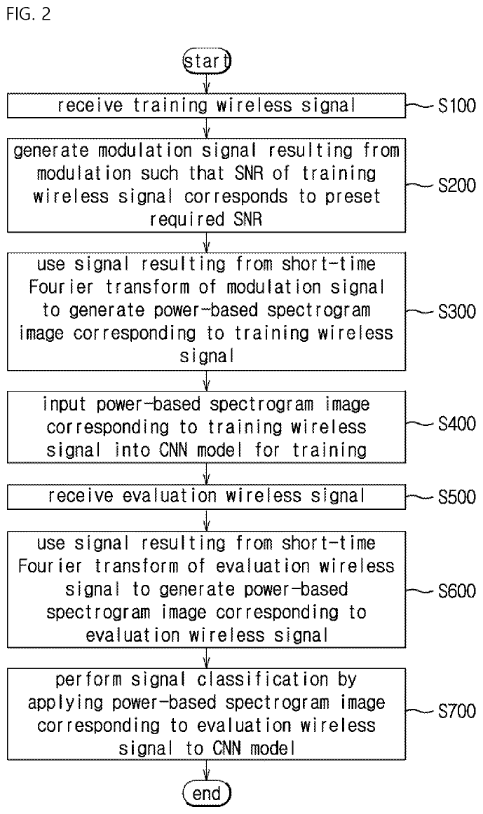

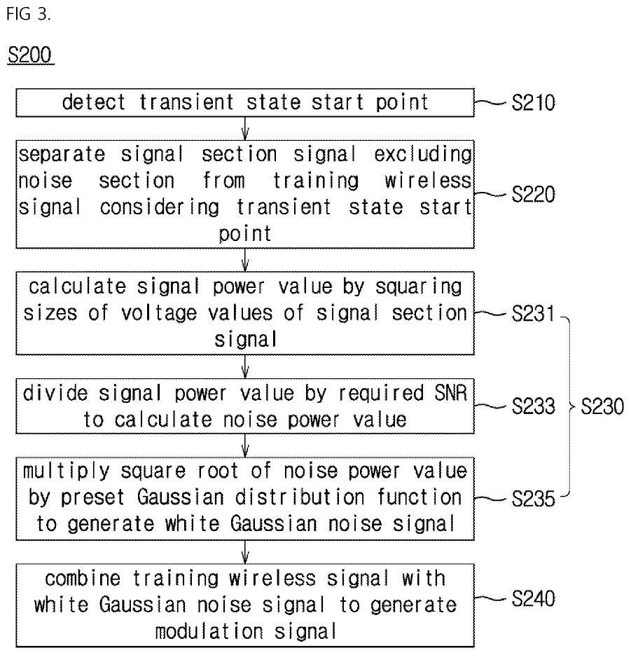

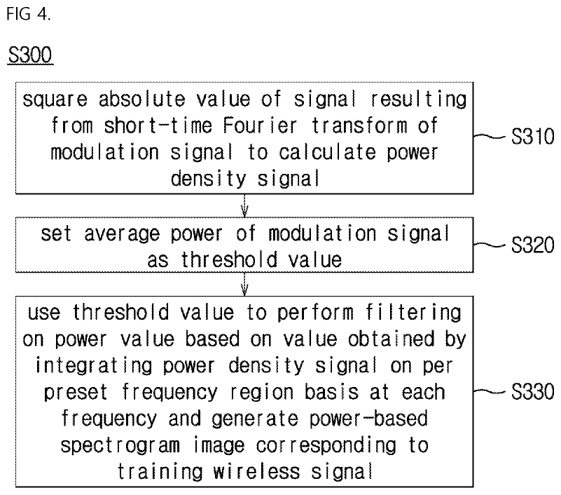

Hereinafter, for convenience of description, functionally identical contents and configurations in FIGS. 1 to 5 are denoted by the same reference numerals and are not repeatedly described.

The wireless training signal input part 110 may receive, from the outside, a wireless training signal, including a plurality of voltage values corresponding to a plurality of time points according to time in operation S100.

The modulation signal generation module 120 may combine the wireless training signal received from the wireless training signal input part 110 with a white Gaussian noise signal according to a preset desired signal-to-noise ratio (SNR) to generate a modulation signal resulting from modulation such that the SNR of the wireless training signal corresponds to the desired SNR, in operation S200.

The modulation signal generation module 120 may include a signal section separation part 121, a noise generation part 123, and a noise combination part 125.

The signal section separation part 121 uses averages of the voltage values of the previous section and the subsequent section with any time point of the wireless training signal in the middle to detect any one time point with a maximum average change among the time points included in the wireless training signal as a transient state start point in operation S210.

Herein, the signal section separation part 121 may use an average change point detection method to detect any one time point included in the wireless training signal as the transient state start point.

The wireless training signal x[n] may be expressed as follows.

x[n]=x₁,x₂, . . . ,x_{N} [Equation 1]

Herein, N denotes the length of the wireless training signal.

The signal section separation part 121 may select any one of the plurality of time points (2, 3, . . . , and N) belonging to the wireless training signal as any time point k.

Next, with any time point k in the middle, the signal section separation part 121 may divide the wireless training signal into a first section xₜ₁ including values (for example, x₁, x₂, . . . , xₖ₋₁) at the time points before the time point k and a second section xₜ₂ including values (for example, xₖ, xₖ₊₁, . . . , x_{N}) at the time point k and the subsequent time points, and may detect, as the transient state start point, any one time point with a maximum variance between the averages of the previous section and the subsequent section with any time point of the wireless training signal in the middle in operation S210.

The signal section separation part 121 may use Equation below to detect any one time point with a minimum value of J(k) as the transient state start point among the plurality of time points (2, 3, . . . , N) belonging to the wireless training signal in operation S210.

$${min}_{J , k ∈ N} J ( k ) = ( \frac{1}{k - 1} ) log ( \frac{1}{k - 1} {\sum }_{i = 1}^{k - 1} {( {x}_{i} - \overline{{x}_{t 1}} )}^{2} ) + ( \frac{1}{N - k + 1} ) log ( \frac{1}{N - k + 1} {\sum }_{i = k}^{N} {( {x}_{i} - \overline{{x}_{t 2}} )}^{2} ) = ( k - 1 ) log ( var ( \overline{{x}_{t 1}} ) ) + ( N - k + 1 ) log ( var ( \overline{{x}_{t 2}} ) ) \qquad [ Equation 2 ]$$

Afterward, the signal section separation part 121 may separate, from the wireless training signal, a signal section signal excluding a noise section and including the plurality of voltage values corresponding to the plurality of time points at and after the transient state start point in operation S220.

With the transient state start point (k) having the minimum value of J(k) in the middle, the signal section separation part 121 may separate the wireless training signal into a noise section signal xₜ₁[i] including the values (for example, x₁, x₂, . . . , xₖ₋₁) at the time points before the time point k and the signal section signal xₜ₂[i] including the values at the time point k and the subsequent time points in operation S220.

The noise generation part 123 may generate the white Gaussian noise signal according to a power ratio of the signal section signal with respect to the preset desired SNR in operation S230.

Specifically, the noise generation part 123 may calculate a signal power value by squaring the sizes of the voltage values of the signal section signal separated from the wireless training signal in operation S231.

The noise generation part 123 may calculate the signal power value P_{signal} according to Equation below in operation S231.

$${P}_{signal} [ W ] = \frac{1}{N - k + 1} {\sum }_{i = k}^{N} {\vert x [ i ] \vert}^{2} = \frac{1}{n} {\sum }_{i = 1}^{n} {\vert {x}_{t 2} [ i ] \vert}^{2} \qquad [ Equation 3 ]$$

Herein, x[i] denotes the wireless training signal, N denotes the length of the wireless training signal, k denotes the transient state start point, xₜ₂[i] denotes the signal section signal, and n denotes the length of the signal section signal.

Afterward, the noise generation part 123 may divide the signal power value P_{signal} by the preset desired SNR to calculate a noise power value in operation S233.

Herein, the desired SNR is set according to a user input, and may be in dB scale or linear scale according to an embodiment.

When a desired SNR γ_{req}[dB] in dB scale is set according to a user input, the noise generation part 123 may convert the desired SNR γ_{req}[dB] in dB scale into a desired SNR γ_{req} in linear scale according to Equation below.

$${γ}_{req} = {10}^{\frac{{γ}_{req} [ dB ]}{10}} \qquad [ Equation 4 ]$$

The noise generation part 123 may divide the signal power value P_{signal} by the desired SNR γ_{req} in linear scale to calculate the noise power value Pₙₒᵢₛₑ in operation S233.

The noise generation part 123 may calculate the noise power value Pₙₒᵢₛₑ by using the signal power value P_{signal} and the desired SNR γ_{req} according to the Equation below in operation S233.

$${P}_{noise} [ W ] = \frac{{P}_{signal}}{{γ}_{req}} \qquad [ Equation 5 ]$$

Afterward, the noise generation part 123 may multiply the square root of the noise power value Pₙₒᵢₛₑ by a preset Gaussian distribution function to generate the white Gaussian noise signal in operation S235.

The noise generation part 123 may generate the white Gaussian noise signal n[i] based on the noise power value Pₙₒᵢₛₑ according to the Equation below in operation S235.

n[i]=\sqrt{Pₙₒᵢₛₑ}N(0,1) [Equation 6]

Herein, with i=1, 2, . . . , n, n denotes the total number of samples of the wireless training signal x[i], and N denotes the Gaussian distribution function with an average of 0 and a variance of 1.

The noise combination part 125 may combine the wireless training signal with the white Gaussian noise signal to generate the modulation signal resulting from modulation such that the SNR of the wireless training signal corresponds to the desired SNR in operation S240.

The noise combination part 125 may combine the wireless training signal x[i] with the white Gaussian noise signal n[i] to generate the modulation signal according to the Equation below in operation S240.

y[i]=x[i]+n[i] [Equation 7]

The wireless evaluation signal input part 130 may receive, from the outside, a wireless evaluation signal including a plurality of voltage values according to time in operation S500, wherein the wireless evaluation signal is to be subjected to signal classification.

After the modulation signal is generated in operation S200, the spectrogram image generation part 140 may use a signal resulting from short-time Fourier transform of the modulation signal to generate a power-based spectrogram image corresponding to the wireless training signal in operation S300.

In addition, after the wireless evaluation signal is received in operation S500, the spectrogram image generation part 140 may use a signal resulting from short-time Fourier transform of the wireless evaluation signal to generate a power-based spectrogram image corresponding to the wireless evaluation signal in operation S600.

The spectrogram image generation part 140 may square an absolute value of the signal resulting from short-time Fourier transform of the modulation signal to calculate a power density signal for the modulation signal in operation S310, may set an average power of the modulation signal as a threshold value in operation S320, and may use the threshold value set for the modulation signal to perform filtering on a power value based on a value obtained by integrating the power density signal for the modulation signal on a per preset frequency region basis at each frequency and may generate the power-based spectrogram image corresponding to the wireless training signal and including a plurality of pixel values corresponding to time and frequency domains in operation S330.

In addition, after the wireless evaluation signal is received in operation S500, the spectrogram image generation part 140 may square an absolute value of the signal resulting from short-time Fourier transform of the wireless evaluation signal to calculate a power density signal for the wireless evaluation signal in operation S610, may set an average power of the wireless evaluation signal as a threshold value in operation S620, and may use the threshold value set for the wireless evaluation signal to perform filtering on a power value based on a value obtained by integrating the power density signal for the wireless evaluation signal on a per preset frequency region basis at each frequency and may generate the power-based spectrogram image corresponding to the wireless evaluation signal and including a plurality of pixel values corresponding to time and frequency domains in operation S630.

The spectrogram image generation part 140 may calculate the power density signal S(m,w) for the modulation signal or the wireless evaluation signal according to the Equation below in operation S310 or S610.

$$STFT ( x [ n ] ) ( m , w ) = X ( m , w ) = {\sum }_{n = - ∞}^{∞} x [ n ] w [ n - mR ] {e}^{- jwn} \qquad [ Equation 8 ]$$

Herein, x[n] denotes either the modulation signal generated by the modulation signal generation module 120 or the wireless evaluation signal input from the wireless evaluation signal input part 130, w[n] denotes a window function, m denotes discrete time, and R denotes a hop size of a window.

S(m,w)=|X(m,w)|² [Equation 9]

Herein, R, a hop size of a window, may be set to the length of the window function w[n].

Accordingly, the amount of operation in spectrogram conversion may be reduced by preventing overlapping portions.

The spectrogram image generation part 140 may set the average power of the modulation signal (or wireless evaluation signal) as the threshold value for the modulation signal (or wireless evaluation signal) in operation S320 or S620.

The spectrogram image generation part 140 may set the threshold value γᵢ for the modulation signal (or wireless evaluation signal) from an average of a power spectrum of the modulation signal (or wireless evaluation signal) according to Equation below in operation S320 of S620.

$${γ}_{t} = 10 {log}_{10} ( \frac{1}{n} {\sum }_{i = 1}^{n} {P}_{limited , i} ) \qquad [ Equation 10 ]$$

Herein, P_{limited,i} denotes the power of the modulation signal (or wireless evaluation signal) from fᵢ to fᵢ₊₁ under condition 0<fᵢ<fᵢ₊₁, and n denotes the length of the modulation signal (or wireless evaluation signal).

Afterward, depending on whether a power value corresponding to each time point and frequency obtained by integrating the power density signal for the modulation signal (or wireless evaluation signal) on a per limited section basis with respect to each frequency exceeds the threshold value set for the modulation signal (or wireless evaluation signal), the spectrogram image generation part 140 may set either the power value or the threshold value as a pixel value of a pixel corresponding to each time point and frequency among pixels corresponding to the time and frequency domains, and may generate the power-based spectrogram image including the plurality of pixel values corresponding to the time and frequency domains in operation S330 or S630.

The spectrogram image generation part 140 may integrate the power density signal for the modulation signal (or wireless evaluation signal) on a per limited section basis with respect to each frequency to calculate a power value Sₚ(m,w) corresponding to each time point and frequency according to Equation below.

Sₚ(m,w)=2∫_{f}_{ᵢ}^{f}^{ᵢ₊₁}S(m,w)df [Equation 11]

When a power value calculated by performing integration on a per limited section basis with respect to each frequency exceeds the threshold value, the spectrogram image generation part 140 sets the power value as a pixel value of a pixel corresponding to a time point and a frequency. When the power value does not exceed the threshold value, the threshold value is set as a pixel value of a pixel corresponding to a time point and a frequency. Accordingly, the power-based spectrogram image, including the plurality of pixel values corresponding to the time and frequency domains, is generated in operation S330 or S630.

The spectrogram image generation part 140 may generate the power-based spectrogram image according to the Equation below in operation S330 or S630.

$${S}_{p} ( m , w ) = \{ \begin{matrix}{S}_{p} ( m , w ) , & if {S}_{p} ( m , w ) > {γ}_{t} \\ {γ}_{t} , & otherwise\end{matrix} \qquad [ Equation 12 ]$$

The training part 150 may input the power-based spectrogram image corresponding to the wireless training signal and a predetermined supervised learning value corresponding to the wireless training signal into a preset CNN model to train the CNN model in operation in operation S400.

The training part 150 may input the power-based spectrogram image corresponding to the wireless training signal and the predetermined supervised learning value corresponding to the wireless training signal into the preset CNN model to train the CNN model in operation S400 such that a spectrogram image is received from the outside and any one of a preset plurality of classification values is output.

The signal classification part 160 may apply the power-based spectrogram image corresponding to the wireless evaluation signal to the CNN model trained by the training part 150 to classify the wireless evaluation signal in operation S700.

As a signal classification apparatus of an unmanned aerial vehicle signal classification system according to another embodiment of the present disclosure, a signal classification apparatus with noise immunity according to another embodiment of the present disclosure may be applied.

Hereinafter, for convenience of description, functionally identical contents and configurations in FIGS. 1 to 6 are denoted by the same reference numerals and are not repeatedly described.

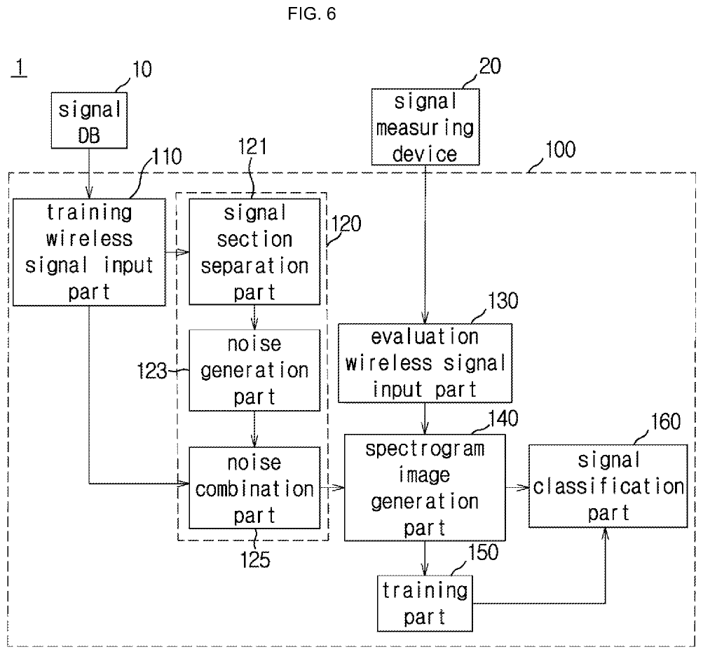

Referring to FIG. 6, an unmanned aerial vehicle signal classification system 1 may include a signal database 10, a signal measuring device 20, and the signal classification apparatus 100.

The signal database 10 may store therein a plurality of wireless training signals respectively corresponding to a plurality of unmanned aerial vehicle (for example, drone) controllers, and classification values respectively corresponding to the plurality of wireless training signals and for classifying the unmanned aerial vehicle controllers.

The signal measuring device 20 may receive an RF signal generated from an external unmanned aerial vehicle controller and may convert the RF signal into electrical energy to generate a wireless evaluation signal having a plurality of voltage values according to time.

The signal measuring device 20 may include an antenna, a high-resolution oscilloscope, and an amplifier, and may receive an RF signal for communication between an external drone and a drone controller, and may generate a wireless evaluation signal to be subjected to signal classification.

The signal classification apparatus 100 may receive the wireless training signals in operation S100, may combine the wireless training signals with white Gaussian noise signals according to a preset desired SNR that a user wants, to generate modulation signals resulting from modulation such that the SNRs of the wireless training signals correspond to the desired SNR in operation S200, may generate power-based spectrogram images corresponding to the wireless training signals from the modulation signals in operation S300, and may input the power-based spectrogram images corresponding to the wireless training signals and classification values corresponding to the wireless training signals as supervised learning values into a preset CNN model to train the CNN model in operation S400.

According to the present disclosure, a wireless training signal previously obtained in an environment, such as an indoor laboratory, is combined with a white Gaussian noise signal according to a desired SNR that a user wants, so that the SNR of the wireless training signal is modulated according to the user's need.

In addition, the CNN model is trained using the wireless training signal of which the SNR is modulated, so that wireless signals with high noise measured in the job site can be accurately classified.

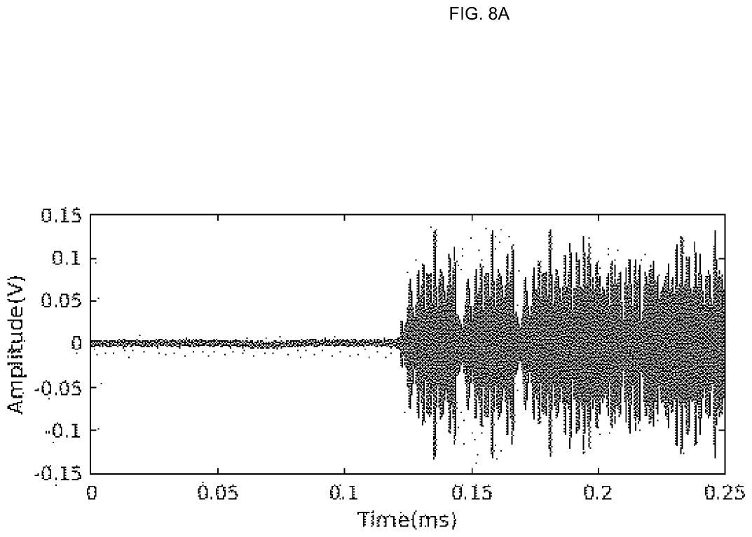

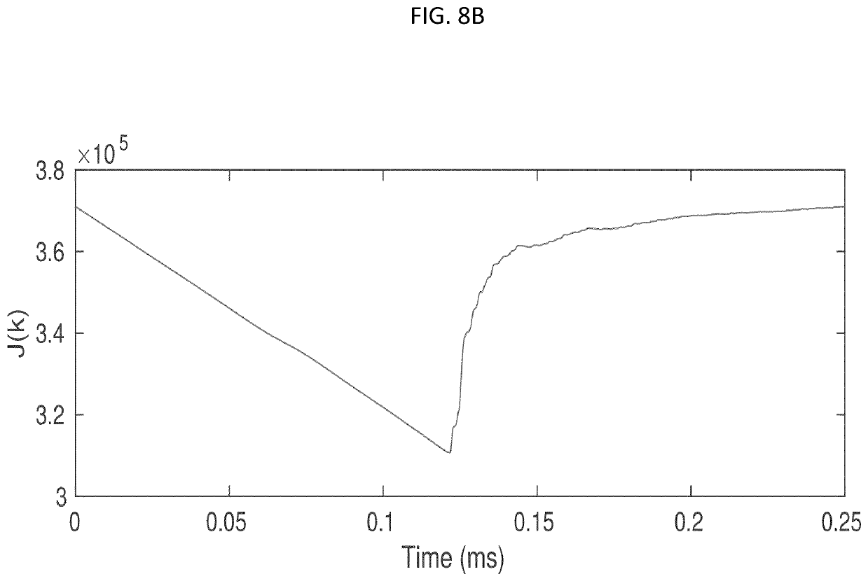

Referring to FIG. 8, the signal classification apparatus 100 may use an average change point detection method to detect a transient state start point with a minimum value of J(k) from a wireless training signal corresponding to each drone in operation S210, and with the transient state start point in the middle, may perform division into a noise section before the transient state start point and a signal section at and after the transient state start point and may separate a signal section signal excluding the noise section from the wireless training signal in operation S220.

Afterward, the signal classification apparatus 100 may generate a white Gaussian noise signal according to a power ratio of the signal section signal with respect to the preset desired SNR in operation S230, and may combine the wireless training signal with the white Gaussian noise signal to generate a modulation signal resulting from modulation such that the SNR of the wireless signal corresponds to the desired SNR in operation S240.

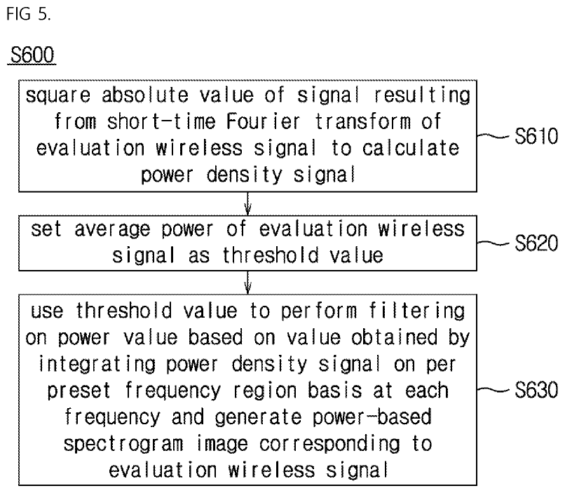

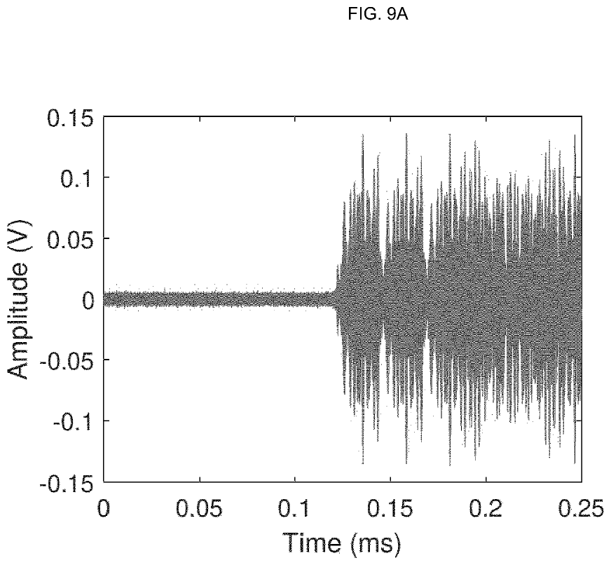

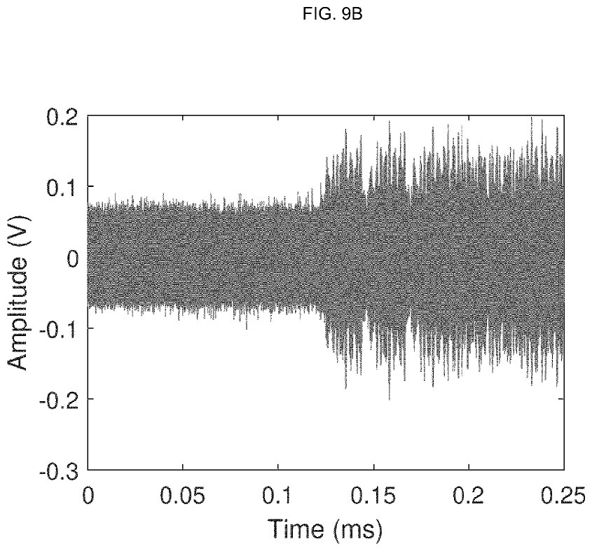

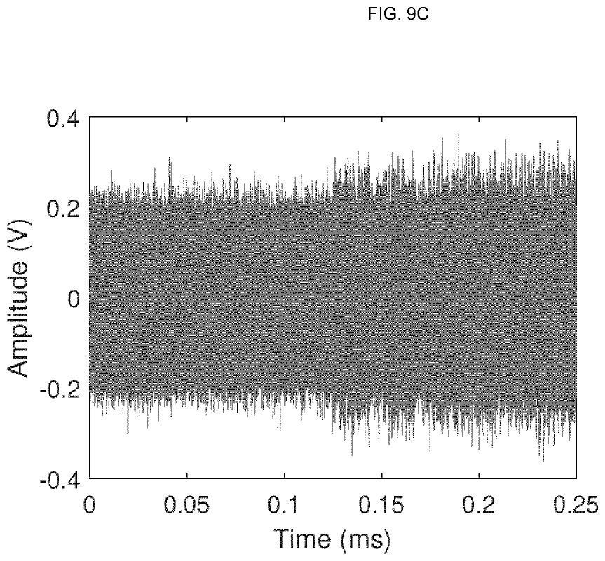

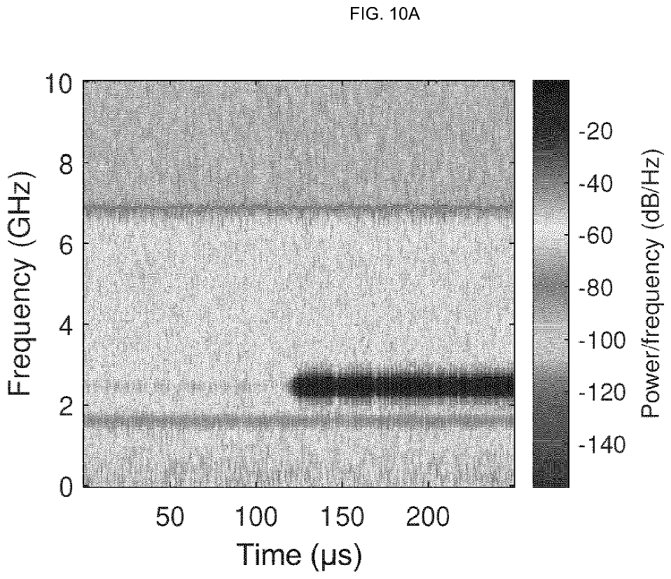

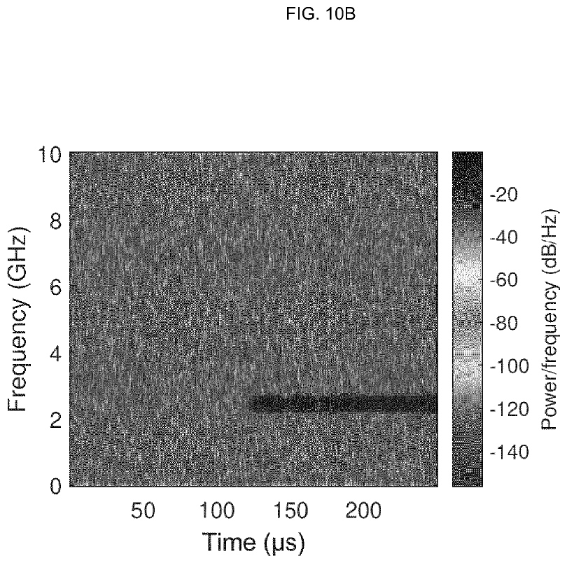

FIG. 9A is a graph illustrating any one wireless training signal applied to the embodiments of the present disclosure. FIG. 9B is a graph illustrating a waveform of a signal obtained by changing the SNR of the wireless training signal of FIG. 9A to 5 dB. FIG. 9C is a graph illustrating a waveform of a signal obtained by changing the SNR of the wireless training signal of FIG. 9A to −5 dB.

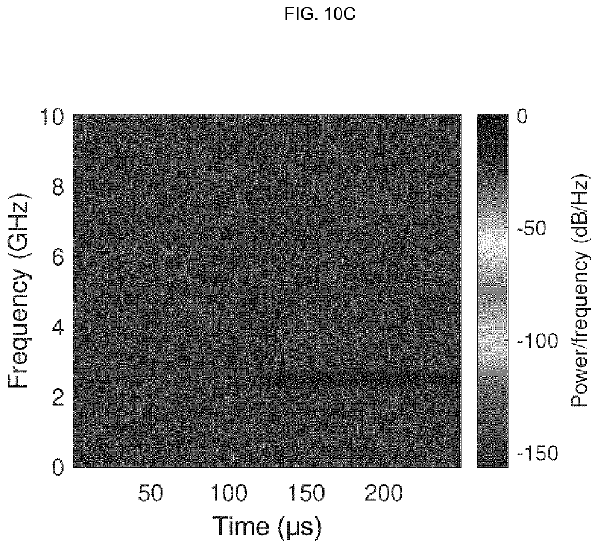

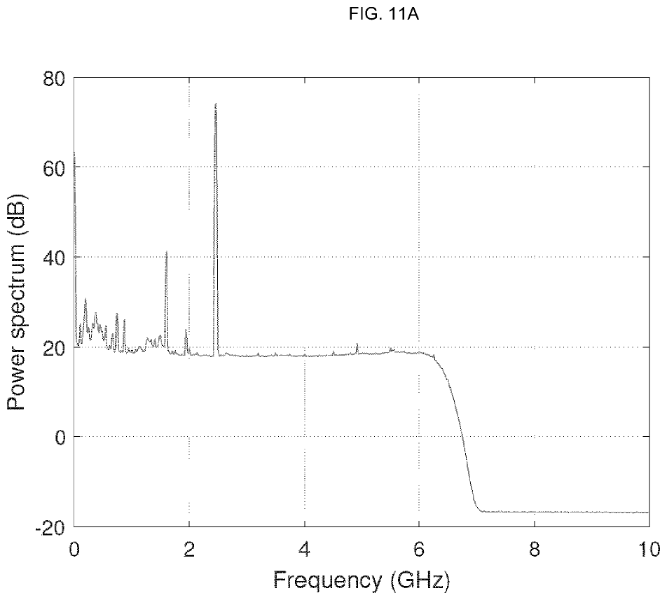

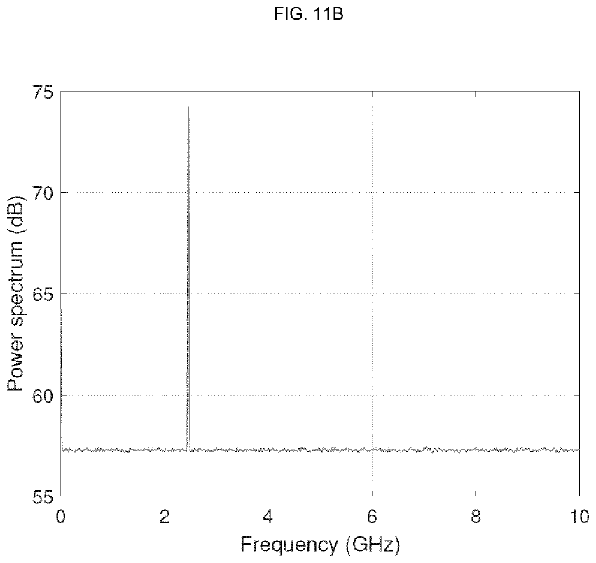

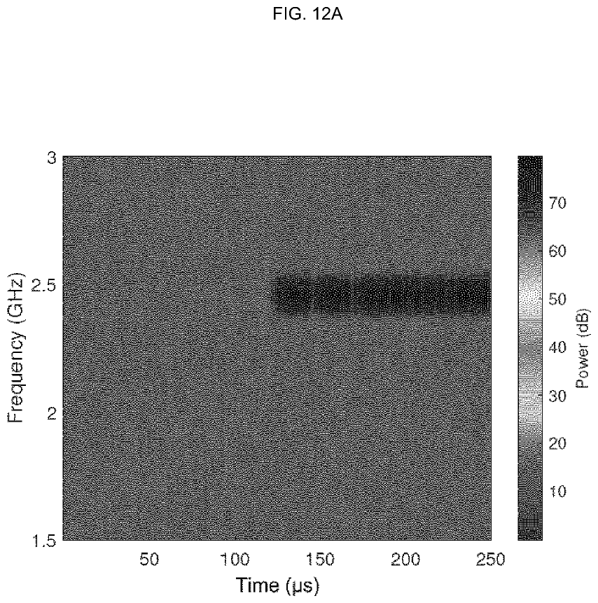

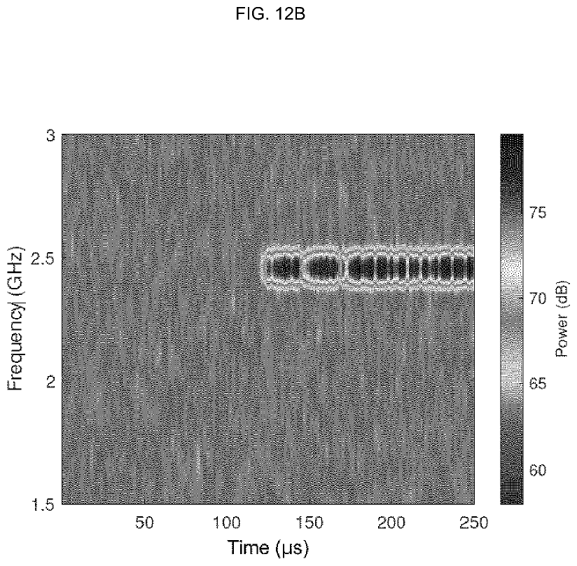

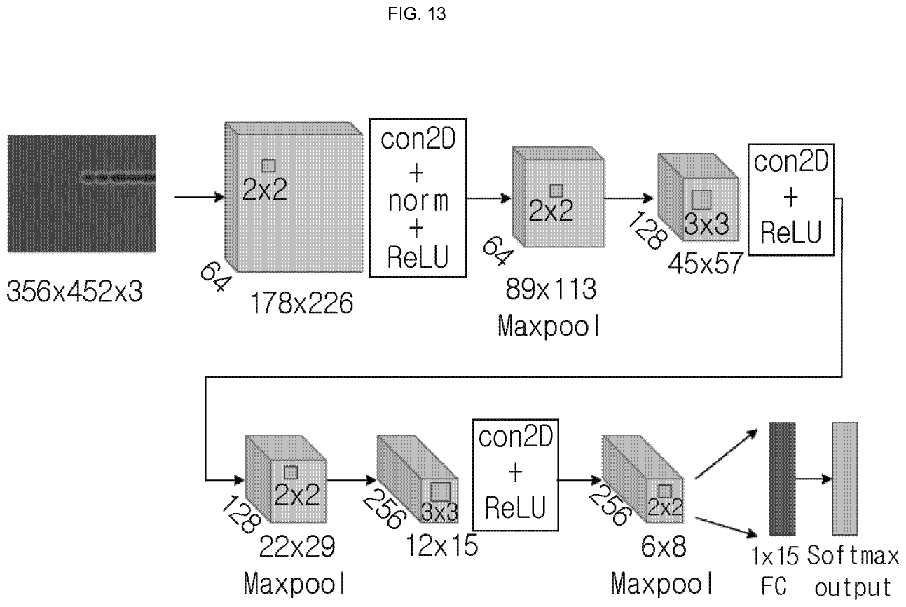

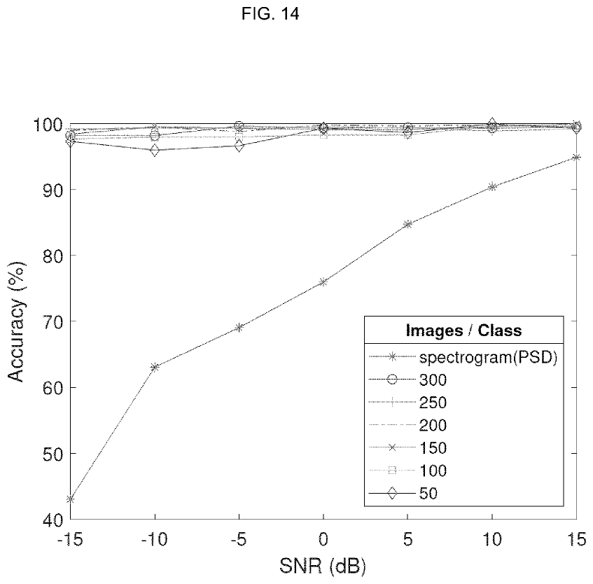

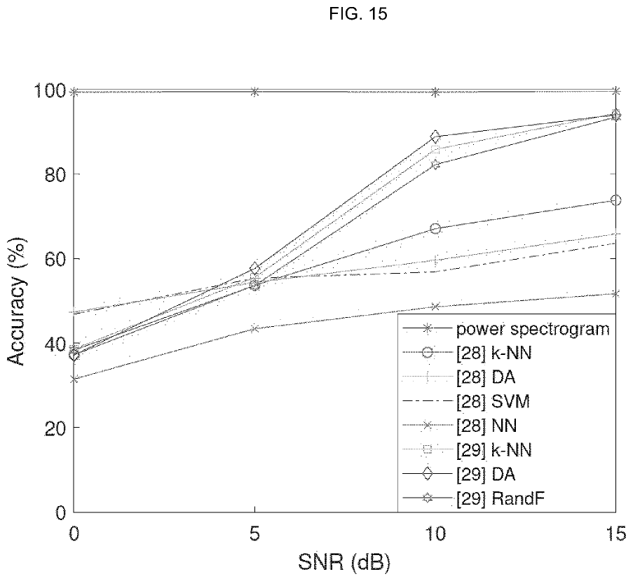

FIG. 10A is a power spectral density-based spectrogram of the wireless training signal of FIG. 9A. FIG. 10B is a power spectral density-based spectrogram of a signal obtained by changing the SNR of the wireless training signal of FIG. 9A to 5 dB. FIG. 10C is a power spectral density-based spectrogram of a signal obtained by changing the SNR of the wireless training signal of FIG. 9A to −5 dB.

Referring to FIGS. 9A to 9C, it was found that the difference between the signal section and the noise section gradually disappeared when the SNR was changed to 5 dB and when the SNR was changed to −5 dB, compared to the original of the wireless training signal.

In addition, referring to FIGS. 10A to 10C, it was found that when the SNR was lowered, the pixel values on the spectrogram were biased to a color.

When the SNR is lowered, noise biases the colors on the spectrogram image. As a result, it is difficult to distinguish the characteristics of signals corresponding to each drone controller, and signal classification accuracy may thus deteriorate.

FIG. 11A is a graph illustrating a power spectrum of any one wireless training signal applied to the embodiments of the present disclosure. FIG. 11B is a graph illustrating a power spectrum of a signal obtained by setting the SNR of the wireless training signal of FIG. 11A to −10 dB.

Referring to FIGS. 11A and 11B, even though the SNR was lowered, a characteristic section having higher power values than other frequency sections on the power spectrum graph was maintained.

Referring to FIG. 12A, it was found that a power-based spectrogram had less bias of colors than a power spectral density-based spectrogram, but the noise was increased, and power spectrum values were increased throughout the frequency domain and thus, the colors were partially biased.

Accordingly, a signal classification apparatus 100 performs short-time Fourier transform on a modulation signal (or wireless evaluation signal) and squares an absolute value to calculate a power density in operation S310 or S610, and sets a power spectrum average of the modulation signal (or wireless evaluation signal) as a threshold value in operation S320 or S620, and uses the threshold value to filter power values resulting from integration of the power density to generate a power-based spectrogram image excluding noise in operation S330 or S630.

Referring to FIG. 12B, it was found that the power-based spectrogram image to which the threshold value was applied according to the embodiments of the present disclosure had a clear difference in color between a characteristic section of a signal and the other sections even at a low SNR.

That is, according to the present disclosure, a spectrogram image showing signal characteristics clearly despite a low SNR can be generated.

The signal classification apparatus 100 inputs the power-based spectrogram image generated from the modulation signal and corresponding to the wireless training signal, to a CNN model to train the CNN model in operation S400, and inputs the power-based spectrogram image generated for the wireless evaluation signal to the trained CNN model to classify the signal in operation S700.

According to the present disclosure, a wireless training signal with any adjusted SNR is used to train a CNN model, thereby improving signal classification accuracy.

In addition, a power-based spectrogram image with noise filtered out using an average power of a wireless signal is input to the CNN model to perform training and signal classification, thereby enabling accurate signal classification even at a low SNR.

Referring to FIG. 13, the CNN model includes: an input layer for receiving a 356×452×3-sized power-based spectrogram image generated by the signal classification apparatus 100; three 2-D convolutional layers; and two max-pooling layers.

Hereinafter, described will be an experiment that was conducted to determine whether classification performance was improved when signal classification is performed according to the embodiments of the present disclosure compared to a conventional signal classification technology.

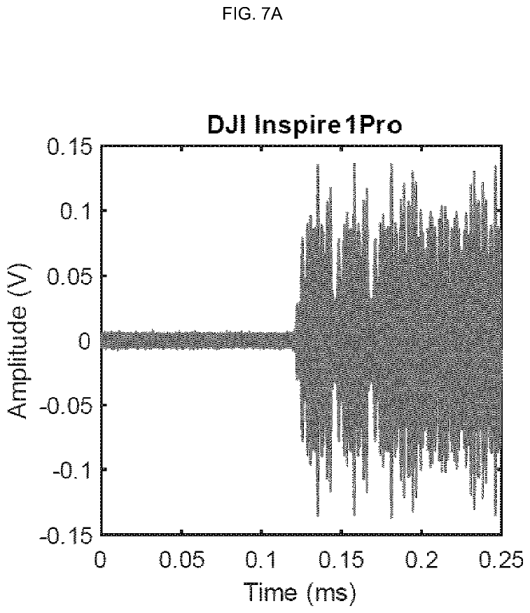

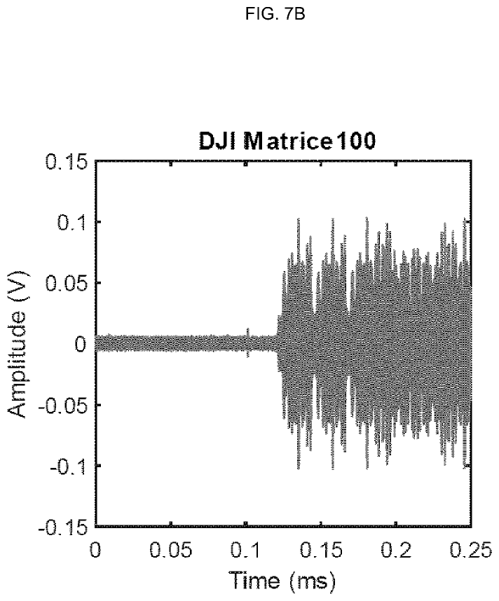

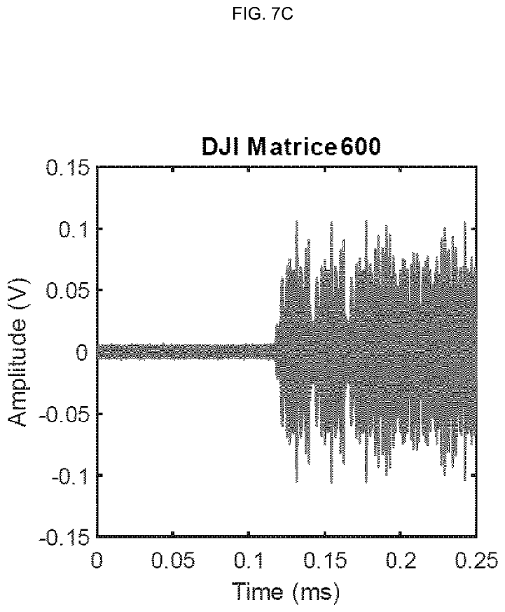

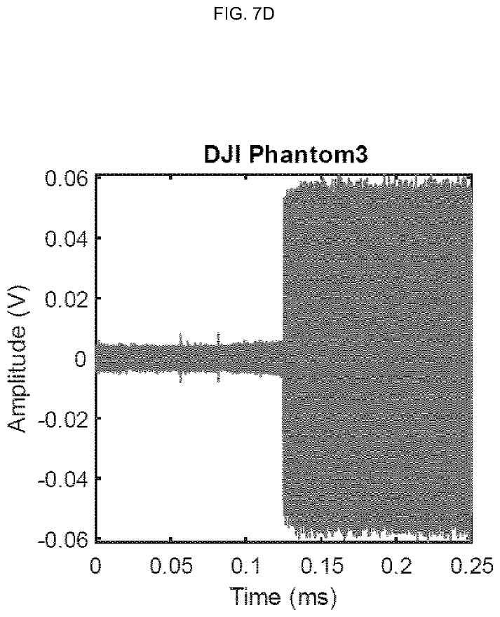

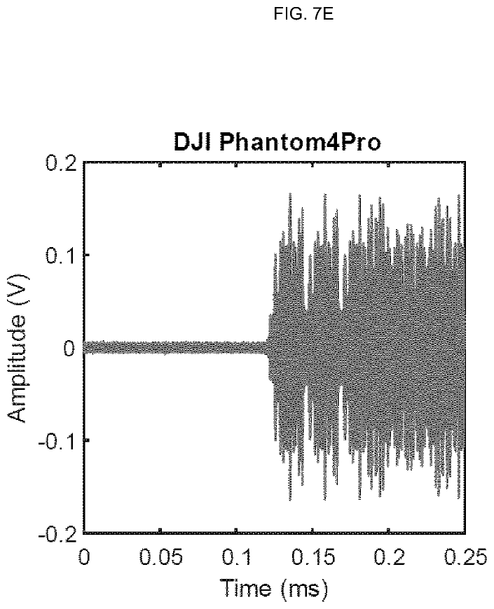

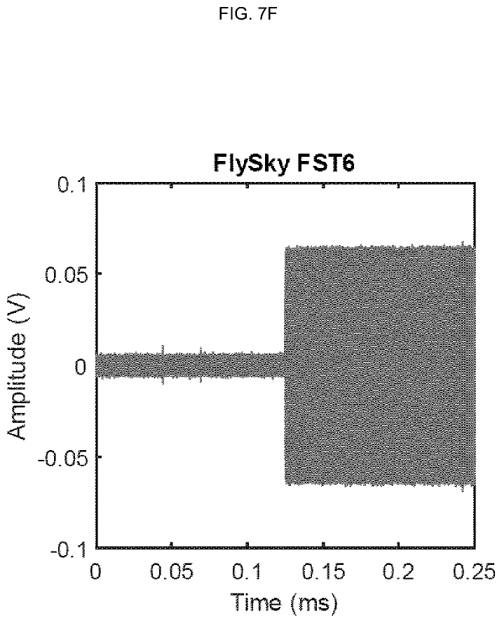

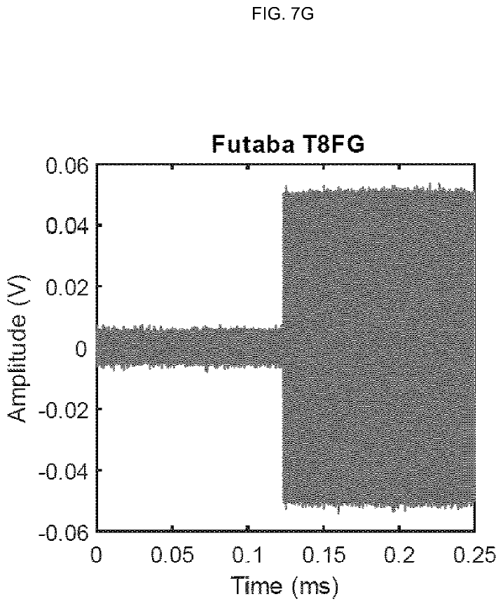

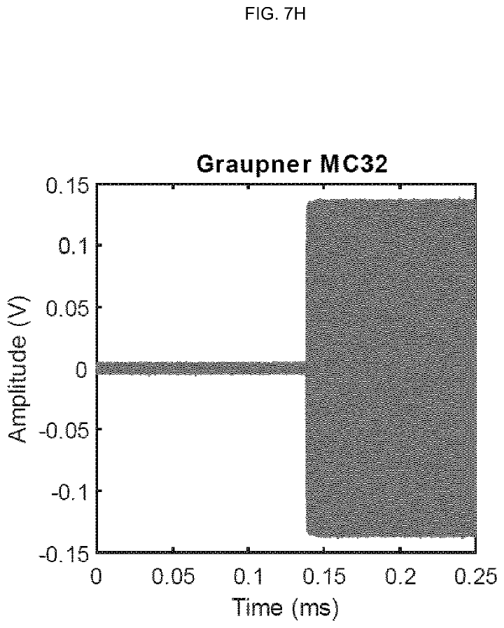

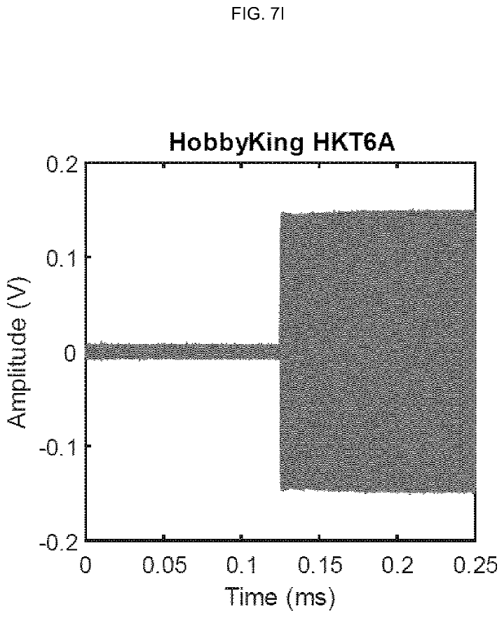

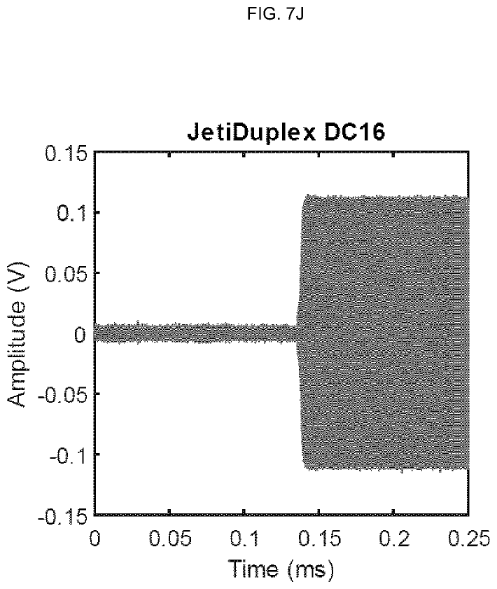

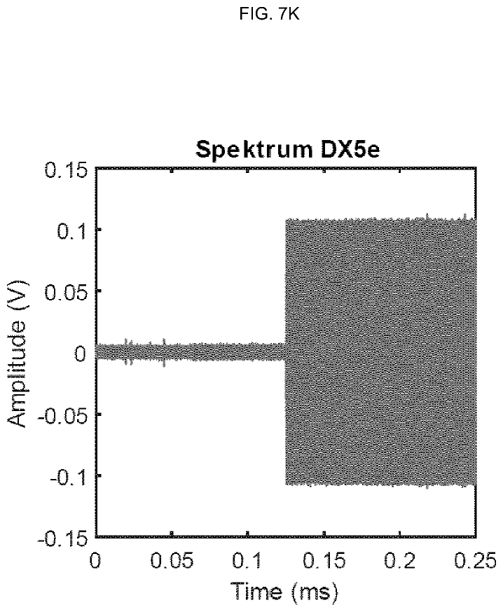

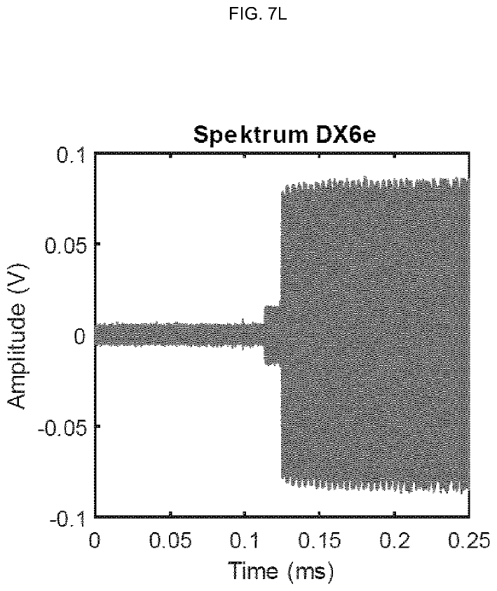

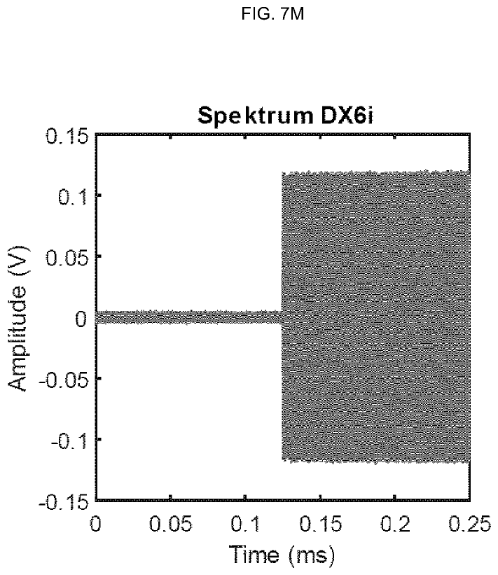

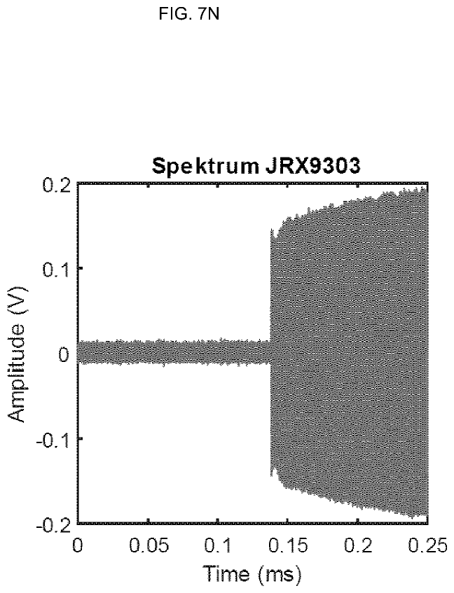

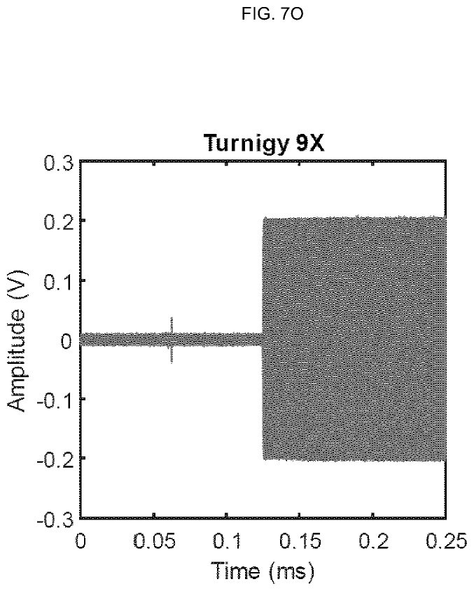

This experiment used RF signals generated from 15 drone controllers produced by eight manufacturers as shown in Table below. The wireless training signal corresponding to each of the plurality of drone controllers shown in Table 1 is the same as that of FIGS. 7A-7O.

TABLE 1

| UAV ID(#) | Brand & Model |
|---|---|
| 1 | DJI Inspire 1 Pro |
| 2 | DJI Matrice 100 |
| 3 | DJI Matrice 600 |
| 4 | DJI Phantom 3 |
| 5 | DJI Phantom 4 Pro |
| 6 | FlySky FST6 |
| 7 | Futaba T8FG |
| 8 | Graupner MC32 |
| 9 | HobbyKing HKT6A |
| 10 | JetiDuplex DC16 |
| 11 | Spektrum DX5e |
| 12 | Spektrum DX6e |
| 13 | Spektrum DX6i |
| 14 | Spektrum JRX9303 |
| 15 | Turnigy 9X |

In addition, the CNN model applied to the embodiments of the present disclosure may have a structure, as shown in FIG. 13 and Table 2 below.

TABLE 2

| Layer | Network Description | Output size |
|---|---|---|
| Input | Spectrogram Image | 356 × 452 × 3 |
| conv1 | 64 filters 2 × 2, stride 2 | 178 × 226 × 64 |
| maxpool1 | pool size 2 × 2, stride 2 | 89 × 113 × 64 |
| conv2 | 128 filters 3 × 3, stride 2 | 45 × 57 × 128 |
| maxpool2 | pool size 2 × 2, stride 2 | 23 × 29 × 128 |
| conv3 | 256 filters 3 × 3, stride 2 | 12 × 15 × 256 |
| maxpool3 | pool size 2 × 2, stride 2 | 6 × 8 × 256 |
| fc | fully connected layer | 1 × 1 × 15 |
| softmax | softmax layer | |

Specifically, the CNN model applied to the embodiments of the present disclosure may be set, as shown in Table 3 below.

TABLE 3

| Option | Value |
|---|---|
| Optimizer | Gradient Descent |
| | Descent with Momentum |
| Momentum factor | 0.9 |
| L2 Regularization factor | 0.0001 |
| Maximum Epoch | 100 |
| Learning rate | 0.01 |
| Learning rate drop factor | 0.1 |
| Learning rate drop epoch | 60 |
| Mini-batch size | 16 |

1. Classification accuracy comparison between a case in which a CNN model for signal classification was trained with a conventional power spectral density-based spectrogram image and a case in which the CNN model was trained with a power-based spectrogram image according to the embodiments of the present disclosure

As an experiment condition, the SNR of the wireless training signal corresponding to each drone controller shown in Table 1 was changed from −15 dB to 15 dB by 5 dB, and with respect to the wireless training signal for each SNR, signal classification accuracy was determined regarding a case in which 300 conventional power spectral density-based spectrogram images were used for training the CNN model and a case in which power-based spectrogram images, increased in number from 50 to 300 by 50, according to the embodiments of the present disclosure were used for training the CNN model.

Referring to FIG. 14, it was found that when the signal classification was performed using the conventional power spectral density-based spectrogram images, the classification accuracy (spectrogram (power spectral density)) was 94.92% with the SNR of 15 dB, and as the SNR lowered, classification accuracy also dropped sharply.

Conversely, it was found that regarding classification accuracy (50, 100, 150, 200, 250, 300) when the signal classification was performed using the power-based spectrogram images according to the embodiments of the present disclosure, the classification accuracy did not drop to 96% or below even though the SNR was reduced to −15 dB regardless of the number of the images.

It was found that classification accuracy (250, 300) when training was performed using 250 and more power-based spectrogram images according to the embodiments of the present disclosure was very high at 99% or higher in the SNR environment ranging from −15 dB to 15 dB.

That is, it was found that compared to using a conventional power spectral density-based spectrogram image for training a signal classification model, using a power-based spectrogram image according to the present disclosure for training the signal classification model improves signal classification accuracy and enables accurate classification regardless of SNR and thus has noise immunity.

2. Classification accuracy comparison between signal classification according to conventional signal classification technologies and signal classification according to the embodiments of the present disclosure

The SNR of the wireless training signal corresponding to each drone controller shown in Table 1 was changed from 0 dB to 15 dB by 5 dB, and classification accuracy was determined regarding a case in which a feature called an RF fingerprint was extracted from the transient signal of the wireless training signal for each SNR and signal classification was performed using each of a plurality of machine learning technologies (k-NN, DA, SVM, NN, and Random Forest), and a case in which the training signal for each SNR was subjected to signal classification according to the embodiments of the present disclosure.

Referring to FIG. 15, it was found that signal classification accuracy dropped significantly as the SNR increased when used were the conventional signal classification technologies in which the feature called the RF fingerprint was extracted from the transient signal of the wireless training signal for each SNR and signal classification was performed using each of the plurality of machine learning technologies (k-NN, DA, SVM, NN, and Random Forest), but the classification accuracy (power spectrogram) when signal classification according to the embodiments of the present disclosure was performed was maintained high despite SNR change.

That is, it was found that signal classification according to the present disclosure maintained classification accuracy stably despite SNR change.

As described above, according to the present disclosure, a white Gaussian noise is added to a wireless training signal for training to modulate the SNR, and application to a CNN model takes place, so that wireless signals with noise measured in the job site can be accurately classified.

In addition, a power-based spectrogram image is generated with a wireless signal rather than a conventional power spectral density-based spectrogram, and in generating the power-based spectrogram image, noise is filtered out using a power spectrum average of the wireless signal, thereby generating the power-based spectrogram image showing signal characteristics clearly regardless of SNR.

Accordingly, higher accuracy than those of the conventional signal classification technologies is achieved, and stable and accurate signal classification is achieved despite SNR change.

The signal classification apparatus 100, wireless training signal input part 110, modulation signal generation module 120, wireless evaluation signal input part 130, spectrogram image generation part 140, training part 150, signal classification part 160, signal database 10, and signal measuring device 20 in FIGS. 1-15 that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-15 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A signal classification method with noise immunity, the method comprising:
receiving a wireless training signal including a plurality of voltage values corresponding to a plurality of time points based on time;
combining the wireless training signal with a white Gaussian noise signal, based on a preset desired signal-to-noise ratio (SNR), to generate a modulation signal resulting from modulating an SNR of the wireless training signal to correspond to the preset desired SNR;
generating, based on a signal resulting from performing short-time Fourier transform on the modulation signal, a power-based spectrogram image corresponding to the wireless training signal;
inputting the power-based spectrogram image and a predetermined supervised learning value corresponding to the wireless training signal into a preset convolution neural network (CNN) model to train the preset CNN model;
receiving a wireless evaluation signal;
generating, based on a signal resulting from performing short-time Fourier transform on the wireless evaluation signal, a power-based spectrogram image corresponding to the wireless evaluation signal; and
classifying the wireless evaluation signal by applying the power-based spectrogram image corresponding to the wireless evaluation signal to the preset CNN model.

2. The method of claim 1, wherein the generating of the modulation signal comprises:
using averages of the voltage values of a previous section and a subsequent section with any intermediate time point, among the time points of the wireless training signal, to detect any one of the time points included in the wireless training signal as a transient state start point with a maximum average change;
separating, from the wireless training signal, a signal section signal excluding a noise section, and including the plurality of voltage values corresponding to the plurality of time points at and after the transient state start point;
generating the white Gaussian noise signal based on a power ratio of the signal section signal with respect to the preset desired SNR; and
combining the wireless training signal with the white Gaussian noise signal to generate the modulation signal resulting from the modulation of the SNR of the wireless training signal to correspond to the desired SNR.

3. The method of claim 2, wherein the generating of the white Gaussian noise signal comprises:
calculating a signal power value by squaring sizes of the voltage values of the signal section signal;
dividing the signal power value by the preset desired SNR to calculate a noise power value; and
generating the white Gaussian noise signal by multiplying a square root of the noise power value by a preset Gaussian distribution function.

4. The method of claim 1, wherein the generating of the power-based spectrogram image corresponding to the wireless training signal comprises:
calculating a power density signal by performing short-time Fourier transform on the modulation signal and by squaring an absolute value of a signal resulting from short-time Fourier transform;
setting an average power of the modulation signal as a threshold value; and
using the threshold value to perform filtering on a power value based on a value obtained by integrating the power density signal on a per preset frequency region basis at each frequency, and generating the power-based spectrogram image including a plurality of pixel values corresponding to time and frequency domains.

5. A signal classification apparatus with noise immunity, the apparatus comprising:
a wireless training signal input part configured to receive a wireless training signal including a plurality of voltage values corresponding to a plurality of time points based on time;
a modulation signal generation module configured to combine the wireless training signal with a white Gaussian noise signal, based on a preset desired signal-to-noise ratio (SNR), to generate a modulation signal resulting from modulating an SNR of the wireless training signal to correspond to the preset desired SNR;
a wireless evaluation signal input part configured to receive a wireless evaluation signal;
a spectrogram image generation part configured to generate a power-based spectrogram image corresponding to the wireless training signal based on a signal resulting from performing short-time Fourier transform on the modulation signal, and generate a power-based spectrogram image corresponding to the wireless evaluation signal on based on a signal obtained by performing short-time Fourier transform on the wireless evaluation signal;
a training part configured to input the power-based spectrogram image corresponding to the wireless training signal and a predetermined supervised learning value corresponding to the wireless training signal into a preset convolution neural network (CNN) model to train the preset CNN model; and
a signal classification part configured to apply the power-based spectrogram image corresponding to the wireless evaluation signal to the preset CNN model trained.

6. The apparatus of claim 5, wherein the modulation signal generation module comprises:
a signal section separation part configured to use averages of the voltage values of a previous section and subsequent section with any intermediate time point, among the time points of the wireless training signal, to detect any one of the time points included in the wireless training signal as a transient state start point with a maximum average change, and separate, from the wireless training signal, a signal section signal excluding a noise section, and including the plurality of voltage values corresponding to the plurality of time points at and after the transient state start point;
a noise generation part configured to generate the white Gaussian noise signal according to a power ratio of the signal section signal with respect to the preset desired SNR; and
a noise combination part configured to combine the wireless training signal with the white Gaussian noise signal to generate the modulation signal resulting from modulation such that the SNR of the wireless training signal corresponds to the desired SNR.

7. The apparatus of claim 6, wherein the noise generation part is further configured to
calculate a signal power value by squaring sizes of the voltage values of the signal section signal, calculate a noise power value by dividing the signal power value by the preset desired SNR, and
generate the white Gaussian noise signal by multiplying a square root of the noise power value by a preset Gaussian distribution function.

8. The apparatus of claim 5, wherein the spectrogram image generation part is further configured to
calculate a power density signal for the modulation signal or the wireless evaluation signal by squaring an absolute value of a signal obtained by performing short-time Fourier transform on the modulation signal or the wireless evaluation signal,
set an average power of the modulation signal or the wireless evaluation signal as a threshold value,
use the threshold value set for the modulation signal or the wireless evaluation signal to perform filtering on a power value based on a value obtained by integrating the power density signal for the modulation signal or the wireless evaluation signal on a per preset frequency region basis at each frequency, and
generate the power-based spectrogram image corresponding to the wireless training signal or the wireless evaluation signal and including a plurality of pixel values corresponding to time and frequency domains.

9. An unmanned aerial vehicle signal classification system, comprising:
a signal database configured to store a plurality of wireless training signals respectively corresponding to a plurality of unmanned aerial vehicle controllers, and a plurality of classification values respectively corresponding to the plurality of wireless training signals;
a signal measuring device configured to receive an RF signal generated from an external unmanned aerial vehicle controller and convert the RF signal into electrical energy to generate a wireless evaluation signal having a plurality of voltage values based on time; and
a signal classification apparatus configured to
combine the wireless training signals with white Gaussian noise signals, based on a preset desired signal-to-noise ratio (SNR), to generate modulation signals resulting from modulating SNRs of the wireless training signals to correspond to the preset desired SNR,
generate power-based spectrogram images corresponding to the wireless training signals from the modulation signals,
input the power-based spectrogram images corresponding to the wireless training signals and the classification values corresponding to the wireless training signals as supervised learning values into a preset convolution neural network (CNN) model to train the preset CNN model,
receive the wireless evaluation signal to generate a power-based spectrogram image corresponding to the wireless evaluation signal, and
apply the power-based spectrogram image corresponding to the wireless evaluation signal to the preset CNN model to classify the wireless evaluation signal.

10. The system of claim 9, wherein the signal classification apparatus comprises:
a wireless training signal input part configured to receive the wireless training signals stored in the signal database;
a modulation signal generation module configured to combine the wireless training signals with the white Gaussian noise signals based on the preset desired SNR to generate the modulation signals resulting from modulation such that the SNRs of the wireless training signals correspond to the desired SNR;
a wireless evaluation signal input part configured to receive the wireless evaluation signal generated from the signal measuring device;
a spectrogram image generation part configured to generate the power-based spectrogram images corresponding to the wireless training signals on based on signals obtained by performing short-time Fourier transform on the modulation signals, and generate the power-based spectrogram image corresponding to the wireless evaluation signal based on a signal obtained by performing short-time Fourier transform on the wireless evaluation signal;
a training part configured to input the power-based spectrogram images corresponding to the wireless training signals and the supervised learning values predetermined corresponding to the wireless training signals into the preset CNN model to train the CNN model; and
a signal classification part configured to apply the power-based spectrogram image corresponding to the wireless evaluation signal to the CNN model trained by the training part to classify the wireless evaluation signal.

11. The system of claim 10, wherein the modulation signal generation module comprises:
a signal section separation part configured to use averages of voltage values of a previous section and a subsequent section with any intermediate time point of each of the wireless training signals to detect any one of the time points included in each of the wireless training signals as a transient state start point with a maximum average change, and separate, from each of the wireless training signals, a signal section signal excluding a noise section, and including the plurality of voltage values corresponding to the plurality of time points at and after the transient state start point;
a noise generation part configured to generate the white Gaussian noise signals based on power ratios of the signal section signals with respect to the preset desired SNR; and
a noise combination part configured to combine the wireless training signals with the white Gaussian noise signals to generate the modulation signals resulting from modulation such that the SNRs of the wireless training signals correspond to the desired SNR.

12. The system of claim 11, wherein the noise generation part is further configured to calculate signal power values by squaring sizes of the voltage values of the signal section signals, calculate noise power values by dividing the signal power values by the preset desired SNR, and generate the white Gaussian noise signals by multiplying square roots of the noise power values by a preset Gaussian distribution function.

13. The system of claim 10, wherein the spectrogram image generation part is further configured to calculate a power density signal for each of the modulation signals or the wireless evaluation signal by squaring an absolute value of a signal obtained by performing short-time Fourier transform on each of the modulation signals or the wireless evaluation signal, set an average power of each of the modulation signals or the wireless evaluation signal as a threshold value, use the threshold value set for each of the modulation signals or the wireless evaluation signal to perform filtering on a power value based on a value obtained by integrating the power density signal for each of the modulation signals or the wireless evaluation signal on a per preset frequency region basis at each frequency, and generate the power-based spectrogram image corresponding to each of the wireless training signals or the wireless evaluation signal and including a plurality of pixel values corresponding to time and frequency domains.

14. A signal classification apparatus with noise immunity, the apparatus comprising:
a wireless evaluation signal input part configured to receive a wireless evaluation signal;
a spectrogram image generation part configured to generate, based on a signal obtained by performing short-time Fourier transform on the wireless evaluation signal, a power-based spectrogram image corresponding to the wireless evaluation signal; and
a signal classification part configured to classify the wireless evaluation signal by applying the power-based spectrogram image corresponding to the wireless evaluation signal to a convolution neural network (CNN) model,
wherein the CNN model is previously trained to receive an external spectrogram image and output any one of a preset plurality of classification values,
wherein wireless training signals respectively corresponding to a plurality of unmanned aerial vehicle controllers are combined with white Gaussian noise signals according to a preset desired SNR to generate modulation signals, an absolute value of a signal resulting from short-time Fourier transform of each of the modulation signals is squared to obtain a power density signal for each of the modulation signals, the power density signal is integrated on a per preset frequency region basis at each frequency to obtain a power value, the power value is filtered with an average power of each of the modulation signals, a value resulting from filtering is set as a pixel value of each pixel corresponding to time and frequency domains to generate power-based spectrogram images corresponding to the wireless training signals, and the power-based spectrogram images corresponding to the wireless training signals and predetermined supervised learning values corresponding to the wireless training signals are input to the CNN model for training.

15. The apparatus of claim 14, wherein the spectrogram image generation part is further configured to calculate a power density signal by performing short-time Fourier transform on the wireless evaluation signal and squaring an absolute value of a signal resulting from short-time Fourier transform, set an average power of the wireless evaluation signal as a threshold value, use the threshold value to perform filtering on a power value based on a value obtained by integrating the power density signal on a per preset frequency region basis at each frequency, and generate the power-based spectrogram image corresponding to the wireless evaluation signal and including a plurality of pixel values corresponding to time and frequency domains.
